(19) United States
(12) Patent Application Publication
(10) Pub. No.: US 2007/0215984 A1
(43) Pub. Date: Sep. 20, 2007

(54) Formation of a multiple crystal orientation substrate

(76) Inventors: Mohamad A. Shaheen, Portland, OR (US); Jack T. Kavlieros, Portland, OR (US); Been-Yih Jin, Lake Oswego, OR (US); Brian S. Doyle, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/377,475

(22) Filed: Mar. 15, 2006

(51) Int. Cl. H01L 29/06; H01L 21/46

(52) U.S. Cl. 257/618; 438/458; 438/459

(57) ABSTRACT

Embodiments of the invention provide a substrate with a first layer having a first crystal orientation on a second layer having a second crystal orientation different than the first crystal orientation. The first layer may have a uniform thickness.

### BACKGROUND

### Background of the Invention

Many integrated circuits, such as microprocessors, make use of N- and P-MOS transistors formed on the same substrate. NMOS transistors function better on a substrate with a <100> crystal orientation. PMOS transistors, in contrast, function better on a substrate with a <110> crystal orientation.

### BRIEF DESCRIPTION OF THE DRAWINGS

FIG. 1a is a cross sectional side view that illustrates a semiconductor substrate according to one embodiment of the present invention.

FIGS. 1b and 1c are top views of the substrate according to various embodiments of the present invention.

FIG. 2 is a flow chart that explains how a substrate may be fabricated, according to one embodiment of the present invention.

FIG. 3 is a cross sectional side view of the first substrate.

FIG. 4 is a cross sectional side view of one embodiment of the first substrate.

FIG. 5 is a flow chart that describes how a first substrate may be formed.

FIGS. 6a-6c are cross sectional side views that illustrate the formation of the substrate as described in FIG. 5.

FIG. 7 is a flow chart that describes how a first substrate may be formed according to yet another embodiment.

FIGS. 8a-8c are cross sectional side views that illustrate the formation of the substrate as described in FIG. 7.

FIG. 9 is a cross sectional side view that illustrates the first substrate being bonded to the second substrate.

FIG. 10 is a cross sectional side view that illustrates the first and second substrates after being bonded together.

FIG. 11 is a cross sectional side view that illustrates the bonded first and second substrates after a portion of the third layer has been removed.

FIG. 12 is a cross sectional side view that illustrates the bonded first and second substrates after substantially all of the remaining portion of the third layer has been removed.

FIGS. 13 through 18 are cross sectional side views that illustrate one use to which the substrate may be put.

FIG. 19 illustrates a system in accordance with one embodiment of the present invention.

### DETAILED DESCRIPTION

In various embodiments, an apparatus and method relating to the formation of a substrate are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order, in series or in parallel, than the described embodiment. Various additional operations may be performed and/or described operations may be omitted in additional embodiments.

I. Overview:

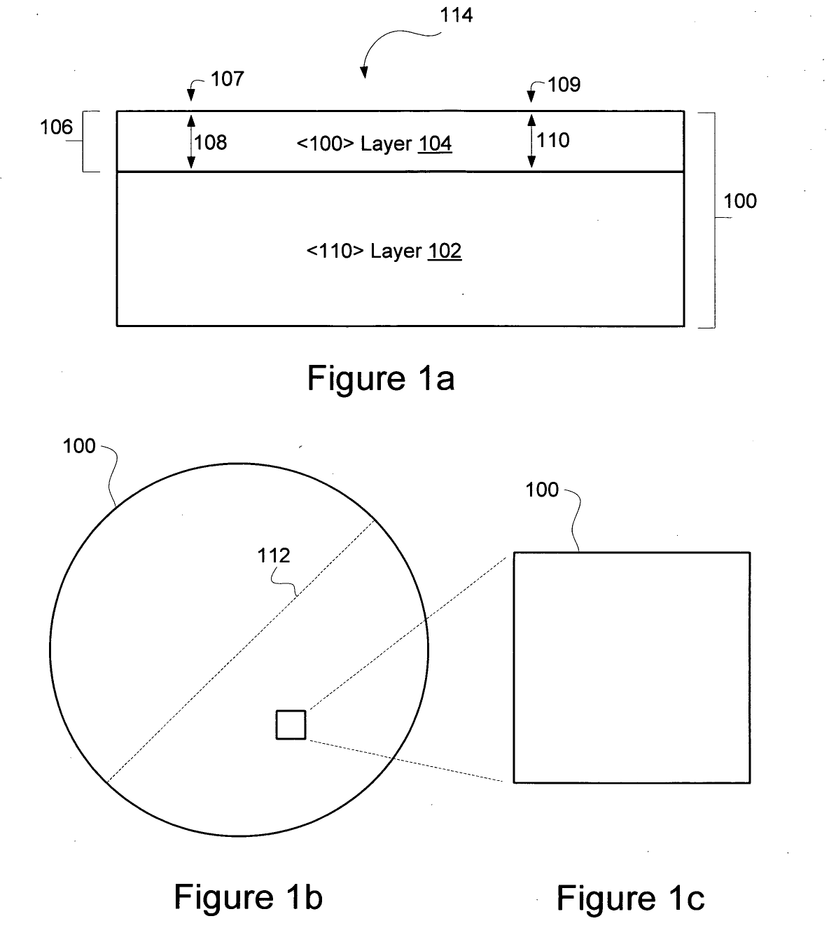

FIG. 1a is a cross sectional side view that illustrates a semiconductor substrate 100 according to one embodiment of the present invention. FIGS. 1b and 1c are top views of the substrate 100 according to various embodiments of the present invention. The substrate 100 may be a composite substrate 100, with a first layer 102 and a second layer 104 on the first layer 102.

Each of the first and second layers 102, 104 may comprise a semiconductor material. In an embodiment, both the first and second layers 102, 104 may comprise the same semiconductor material. In an embodiment, the first and second layers 102, 104 may both comprise silicon. In an embodiment, the first and second layers 102, 104 may both comprise single crystal silicon. In other embodiments, the first and second layers 102, 104 may comprise other materials, such as silicon germanium, gallium arsenide, or other materials.

Each of the first and second layers 102, 104 may have a different crystal orientation. For example, in the illustrated embodiment, the first layer 102 is a silicon layer with a <110> crystal orientation and the second layer 104 is a silicon layer with a <100> crystal orientation. In another embodiment, the first layer 102 may have a <100> crystal orientation and the second layer 104 may have a <110> crystal orientation. In other embodiments, the first and second layers 102, 104 may have other crystal orientations that differ from each other and/or may comprise different materials.

The second layer 104 may have a thickness 106. The thickness 106 may be the average thickness of the second layer 106 in an embodiment, with various points 107, 109 of the second layer 104 having slightly different thicknesses 108, 110 than the average thickness 106. In an embodiment, the thickness 106 may be about one micron or less. In another embodiment, the thickness 106 may be between about 10 angstroms and about one micron. In another embodiment, the thickness 106 may be between about 150 angstroms and about 350 angstroms. In another embodiment, the thickness 106 may be about 250 angstroms. In other embodiments, the thickness 106 may be different. In an embodiment, the thicknesses 108, 110 at various points 107, 109 of the layer 104 may vary less than five angstroms from the average thickness 106 (i.e. the maximum difference between the average thickness 106 and the thickness at any point is less than five angstroms). In an embodiment, the maximum difference between the average thickness 106 and the thickness at any point may be less than or equal to about two angstroms. In an embodiment, the maximum difference between the average thickness 106 and the thickness at any point may be less than or equal to about one angstrom. In other embodiments, there may be different maximum differences between the average thickness 106 and the thickness at any point of the layer 104.

In some embodiments, the substrate 100 may be free of pits in the top surface 114. In an embodiment, the crystal lattice of the semiconductor material of the second layer 104 of the substrate may have a dislocation density of less than about 100/cm² in an embodiment. In anther embodiment, the second layer 104 may have a dislocation density of about 10/cm² or less.

FIGS. 1b and 1c are top views that show the top surface 114 of the substrate 100, according to some embodiments. In the embodiment shown in FIG. 1b, the substrate 100 is a wafer. The substrate 100 may have a substantially circular-shaped top surface, as shown in FIG. 1b. The wafer may have a diameter 112 greater than or equal to about 200 millimeters in one embodiment. In another embodiment, the wafer may have a diameter 112 greater than or equal to about 300 millimeters. Other diameters 112 are possible in other embodiments.

In the embodiment shown in FIG. 1c, the substrate 100 is a portion of a wafer that has been singulated from the wafer, such as is done for a microprocessor die singulated from a wafer. The substrate 100 may have a substantially rectangular shape, as shown in FIG. 1c. The substrate 100 in the embodiment shown in FIG. 1c may have a maximum width of significantly less than 200 millimeters.

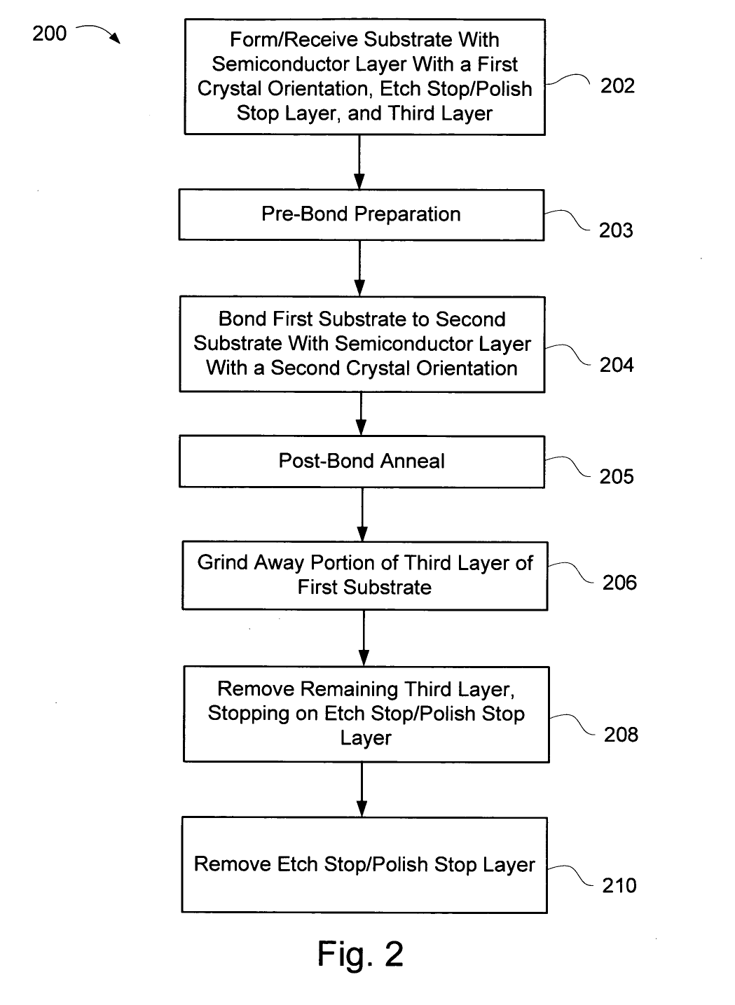

FIG. 2 is a flow chart 200 that explains how a substrate 100 may be fabricated in general, according to some embodiments of the present invention. More detail on how various embodiments of the substrate 100 may be fabricated is presented below. A first substrate having a semiconductor layer with a first crystal orientation, an etch stop or polish stop layer, and a third layer may be formed or received 202. The first substrate may be bonded 204 to a second substrate having a semiconductor layer with a second crystal orientation different than the first crystal orientation. The semiconductor layer with a first crystal orientation of the first substrate may be directly bonded 204 to the semiconductor layer with the second crystal orientation of the second substrate. Prior to bonding, both wafers may be first prepared 203 with cleaning, surface activation or growth of bonding layer to facilitate high strength-void free bonding. In some embodiments, the correct surface activation can be achieved by hydrophobic, hydrophilic, direct surface states or other methods. Any treatment that results in such termination may be used. In an embodiment, the substrates may be cleaned with HF prior to bonding. Following the bonding, a high temperature anneal 205 step to strengthen the bond interface may be carried out at temperatures ranging from 300 degrees Celsius to 1100 degrees Celsius. In an embodiment, the bonded substrates may be annealed 205 at about 600 degrees Celsius.

A grinding or other process may remove 206 a portion of the third layer of the first substrate. The grinding process may result in large variations of thickness. For example, the remaining third layer may have an average thickness of about twenty microns and the thickness of the remaining third layer at various points may vary by plus or minus five microns after grinding. As the second layer 104 may have a thickness less than five microns, if such thickness variations were transferred to the second layer 104, the second layer may be completely removed in some areas of the substrate 100.

Substantially all of the rest of the third layer may then be removed 208 by an etching or polishing process. If the first substrate has an etch stop layer, an etching process may be used, while if the first substrate has a polish stop layer, a polishing process may be used. The etch stop or polish stop layer may substantially remove the thickness variations left after grinding 206, and prevent these variations from being transferred to the second layer 104. Further, the etch stop layer may substantially prevent pits from forming as a result of long etch periods used to remove 208 the rest of the third layer.

The etch stop or polish stop layer may then be removed 210. This may leave behind the semiconductor layer with the first crystal orientation bonded to the semiconductor layer with the second crystal orientation, similar to the substrate 100 illustrated in FIG. 1a. After removal 210 of the etch stop or polish stop layer, the thickness of the second layer 104 may be quite uniform, with small variations (such as maximum variations of 1-5 angstroms) from the average thickness 106; the etch stop or polish stop layer may have effectively prevented the thickness variations of the grinding 206 process from being transferred to the second layer 104.

II. Formation of First Substrate

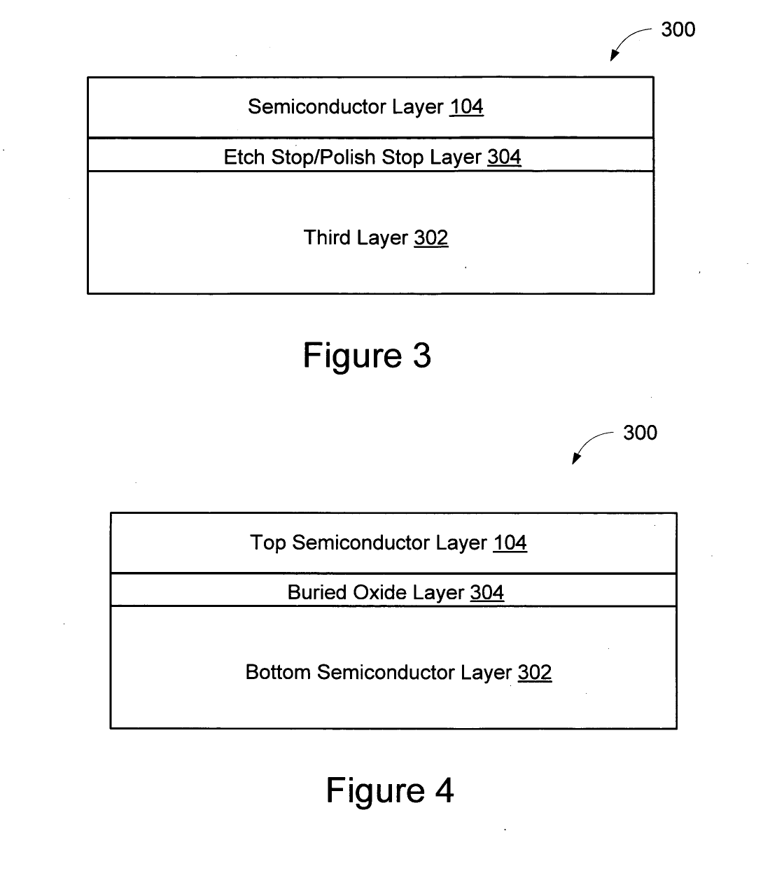

FIG. 3 is a cross sectional side view of the first substrate 300 that may be formed or received 202 as described with respect to the flow chart 200, according to one embodiment of the present invention. The first substrate 300 may include a semiconductor layer 104 with a first crystal orientation, an etch stop or polish stop layer 304, and a third layer 302, as described above with respect to FIG. 2. At least a portion of the semiconductor layer 104 may become the second layer 104 of the composite substrate 100. The etch stop or polish stop layer 304 may have a thickness of between about 1500 angstroms and about 2000 angstroms in some embodiments, although it may have a different thickness in other embodiments. The third layer 302 may comprise a semiconductor material or another type of material. In some embodiments, the third layer 302 may comprise the same material as the semiconductor layer 104. Note that the same reference numbers 104, 300, 302, and 304 are used in the various embodiments. In these various embodiments, the materials, crystal orientation, and/or other aspects of the second layer 104, the third layer 302 of the first substrate 300, and the etch stop/polish stop layer 304 may be used. However, as each of the layers across the various embodiments perform substantially the same function, the reference numbers remain consistent.

The etch stop/polish stop layer 304 may be an etch stop layer in an embodiment. In such an embodiment, the material of the etch stop layer 304 may be chosen so a selected etch chemistry may remove 208 the third layer 302 and stop at the etch stop layer 304. This may occur because the selected etch chemistry may etch the third layer 302 at a greater rate than the etch stop layer 304. In an embodiment, the etch chemistry may remove 208 the third layer 302 at a rate of at least 100 times greater than it removes the etch stop layer 304. In an embodiment, the etch chemistry may remove 208 the third layer 302 at a rate of about at least 1000 times greater than it removes the etch stop layer 304. In other embodiments, the etch selectivity may be different. Another etch chemistry may be selective to the etch stop layer 304 relative to the semiconductor layer 104 so the etch stop layer 304 may be removed 210, leaving the semiconductor layer 104 substantially intact. This etch chemistry may have a selectivity of the etch stop layer 304 to the semiconductor layer 104 of greater than 100:1, greater than 1000:1, or a different selectivity.

In another embodiment, the etch stop/polish stop layer 304 may be a polish stop layer in an embodiment. In such an embodiment, the material of the polish layer 304 may be chosen so a selected polish process may remove 208 the third layer 302 and stop at the polish stop layer 304. This polish process may have a selectivity of the third layer 302 to the polish stop layer 304 of greater than 100:1, greater than 1000:1, or a different selectivity. There may be a similar polish selectivity between the polish stop layer 304 and the semiconductor layer 104, allowing removal 210 of the polish stop layer 304 without significantly affecting the semiconductor layer 104.

In another embodiment, the etch stop layer 304 may comprise a material that acts as an etch stop for removal 208 of the third layer 302, and then the etch stop layer 304 may be removed 210 by polishing without significantly affecting the semiconductor layer 104. In yet another embodiment, the polish stop layer 304 may comprise a material that acts as a polish stop for removal 208 of the third layer 302, and then the polish stop layer 304 may be removed 210 by etching without significantly affecting the semiconductor layer 104.

FIG. 4 is a cross sectional side view of one embodiment of the first substrate 300. In the embodiment illustrated in FIG. 4, the first substrate is a silicon-on-insulator (SOI) substrate 300. The SOI substrate 300 shown in FIG. 4 includes a bottom semiconductor layer 302 as the third layer 302, a buried oxide layer 304 as the etch stop/polish stop layer 304, and a top semiconductor layer 104 as the semiconductor layer 104. The bottom semiconductor layer 302 of the SOI substrate 300 may consist substantially of the same material as the top semiconductor layer 104 of the substrate 300 in some embodiments, although in other embodiments the layers 104, 302 may comprise differing materials or different crystal orientations. The buried insulator layer 304 may be etched at a different rate than semiconductor layers 104, 302, allowing it to be used as an etch stop layer 304 (or similarly have a different polish rate allowing it to be used as a polish stop layer 304). The SOI substrate 300 may be formed by any suitable method. An SOI-like wafer with a <110>/Oxide/<100> Si or a <110>/oxide/<110> substrate or combinations or other orientations can be used depending on the desired final combination.

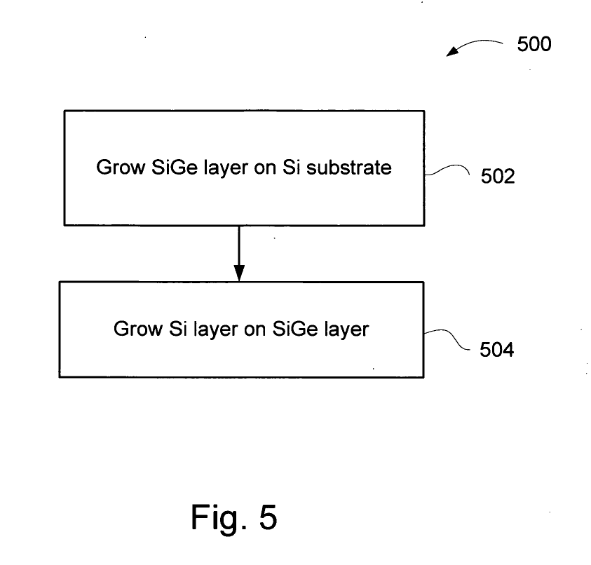

FIG. 5 is a flow chart 500 that describes how another embodiment of the first substrate 300 may be formed 202. A silicon germanium layer may be grown 502 on a silicon substrate. Then a silicon layer may be grown 504 on the silicon germanium layer. SiGe (or another material grown in other embodiments) may have a different etch rate than Si, allowing its use as an etch stop layer 304 (or similarly have a different polish rate allowing it to be used as a polish stop layer 304). In other embodiments, other materials may be used with a similar growth idea: a layer comprising a second material may be grown on a layer comprising a first material, and another layer comprising the first material grown on the layer comprising the second material.

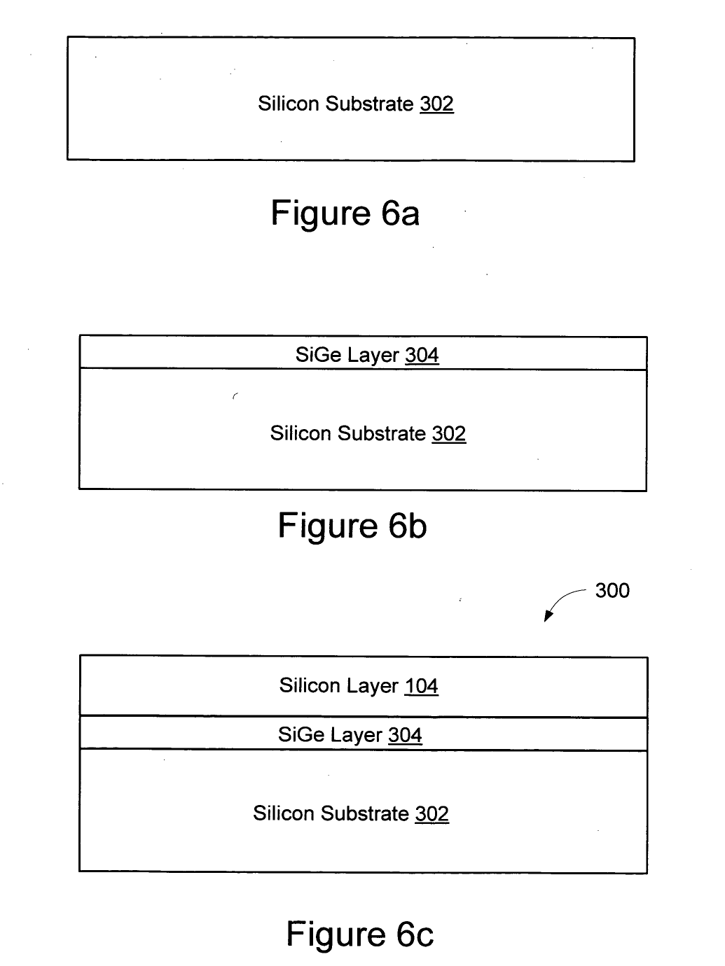

FIGS. 6a through 6c are cross sectional side views that illustrate fabrication of the first substrate 300 according to the embodiment described by the flow chart 500 of FIG. 5, discussed above. FIG. 6a is a cross sectional side view that illustrates the silicon substrate 302 on which silicon-germanium may be grown 502. In an embodiment, the silicon substrate 302 may be a single crystal silicon substrate. FIG. 6b is a cross sectional side view that illustrates a layer of silicon germanium 304 grown 502 on the silicon substrate 302. In an embodiment, the silicon germanium layer 304 may include about 20% germanium and 80% silicon, but other ratios may be used in other embodiments. Any suitable method may be used to grow 502 the silicon germanium layer 302. FIG. 6c is a cross sectional side view that illustrates the silicon layer 104 grown 304 on the silicon germanium layer 304, resulting in the completed first substrate 300. In an embodiment, the silicon layer 104 may be, but is not necessarily, a single crystal silicon material. The silicon germanium layer 304 may be etched at a different rate in a selected etchant than the silicon substrate 302 or silicon layer 104, allowing selective removal of the silicon substrate 302 from the silicon germanium layer 304 and selective removal of the silicon germanium layer 304 from the silicon layer 104.

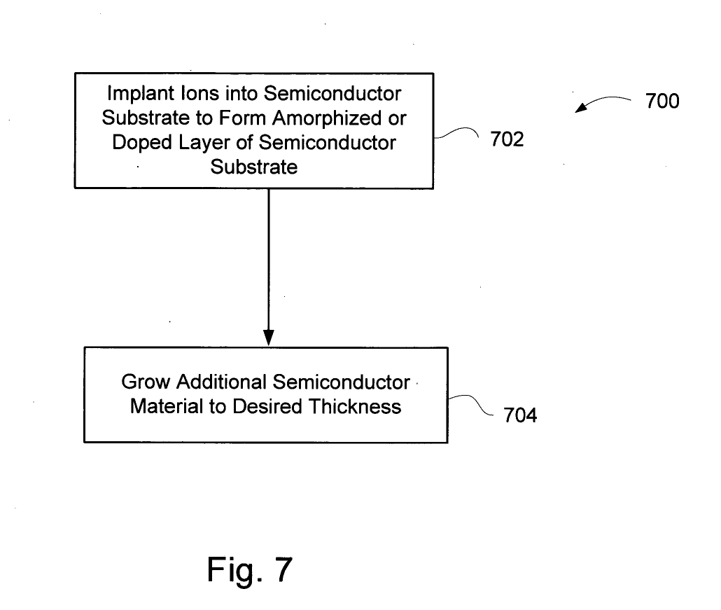

FIG. 7 is a flow chart 700 that describes yet another embodiment of how a first substrate 300 may be formed 202. Ions may be implanted 702 into a semiconductor substrate. In one embodiment, the ions may amorphize some of the material of the semiconductor substrate, forming an amorphized layer of the semiconductor substrate. In another embodiment, the ions may form a doped layer of the semiconductor substrate. In some embodiments, if the ions are not implanted 702 to form a doped or amorphized layer as deep as is desired, additional semiconductor material may be grown 704 to increase the thickness of the layer of semiconductor material on the doped or amorphized layer. The doped or amorphized layer may have a different etch rate than the original material, allowing its use as an etch stop layer 304 (or similarly have a different polish rate allowing it to be used as a polish stop layer 304).

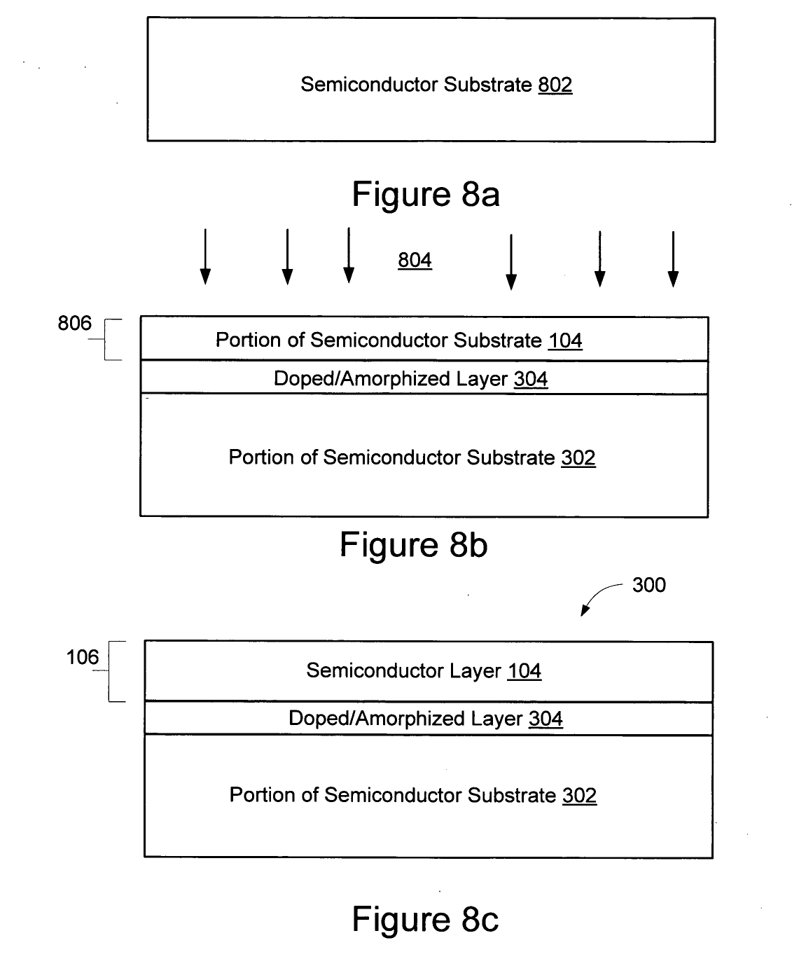

FIGS. 8a through 8c are cross sectional side views that illustrate fabrication of the first substrate 300 according to the embodiment described by the flow chart 700 of FIG. 7, discussed above. FIG. 8a is a cross sectional side view that illustrates the semiconductor substrate 802 into which ions may be implanted 702. In an embodiment, the semiconductor substrate 802 may comprise single crystal silicon, although other materials may be used. FIG. 8b is a cross sectional side view that illustrates ions 804 being implanted 702 into the semiconductor substrate 802. The ions 804 may form a doped layer 304 within the semiconductor substrate 802 in some embodiments. In other embodiments, the ions 804 may amorphize the material of the semiconductor substrate 802 to form an amorphized layer 304. There may be a portion of the semiconductor substrate 302 beneath the doped/amorphized layer 304 and a portion of the semiconductor substrate 104 above the doped/amorphized layer 304.

The conditions of the ion implantation 702 may be chosen so the doped or amorphized layer 304 is a depth 806 beneath the surface of the semiconductor substrate 804. This depth 806 may be less than the desired thickness 106 of the second layer 104 of the composite substrate 100 in some embodiments, although in others the depth 806 may be greater than or equal to the thickness 106. In embodiments where the depth 806 is less than the desired thickness 106 of the second layer 104 of the composite substrate 100, additional semiconductor material may be added or grown 704 on the portion of the semiconductor substrate 104 above the doped/amorphized layer 304 to increase the depth 806 to be the thickness 106 of the second layer 104 of the composite substrate 100. FIG. 8c is a cross sectional side view that illustrates the first substrate 300 after additional semiconductor material has been added or grown 704 on the portion of the semiconductor substrate 104 above the doped/amorphized layer 304 to increase the depth 806 as desired, resulting in the completed first substrate 300. The doped/amorphized layer 304 may be etched or polished at a different rate in a selected etchant or polishing process than the portion of the semiconductor substrate 302 or semiconductor layer 104, allowing selective removal of the portion of the semiconductor substrate 302 from the doped/amorphized layer 304 and selective removal of the doped/amorphized layer 304 from the semiconductor layer 104.

III. Formation of Substrate 100 from First and Second Substrates

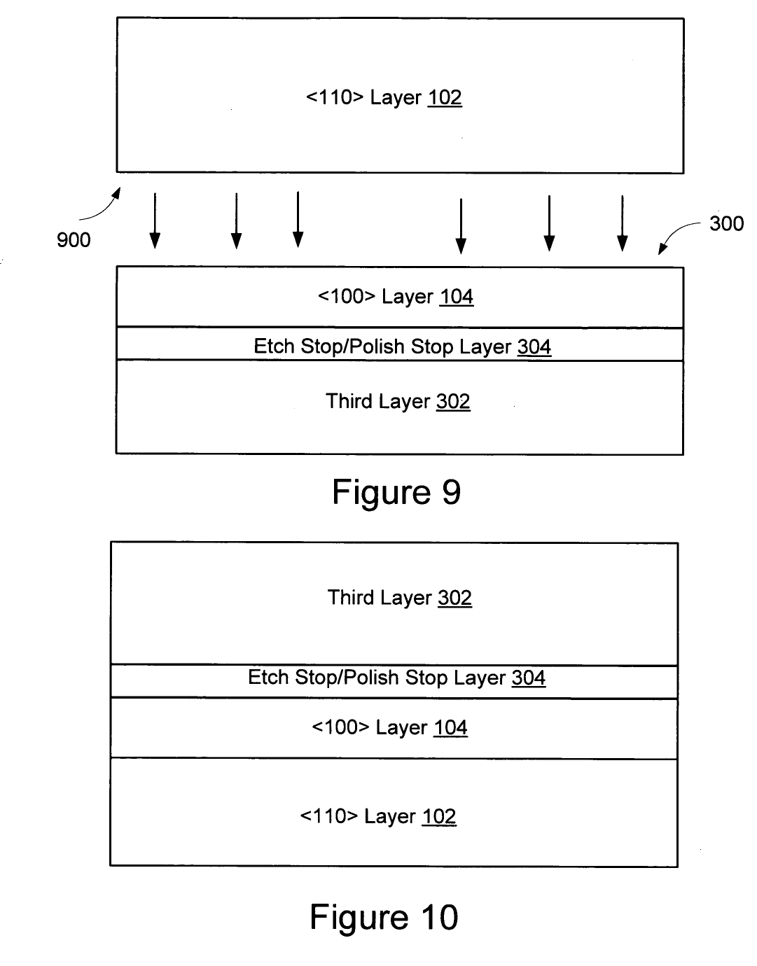

FIG. 9 is a cross sectional side view that illustrates the first substrate 300 being bonded 204 to the second substrate 900, and FIG. 10 is a cross sectional side view that illustrates the first and second substrates 300, 900 after being bonded 204 together. Note that in FIG. 10 the third layer 302 is illustrated as being on top while in FIG. 9 the third layer was illustrated as being on the bottom. The first substrate 300 may be formed according to any one of the embodiments described above, or a different way. The second substrate 900 may include only the first layer 102, or may include other layers and/or structures in addition to the first layer 102. The first layer 102 may have a thickness of about 750 microns in an embodiment, although it may have a greater or smaller thickness in other embodiments. The first and second substrates 300, 900 may be bonded 204 so that the first layer 102 with the first crystal orientation is in contact with the second layer 104 with the second crystal orientation. Any suitable method may be used to bond 204 the first and second substrates 300, 900 together.

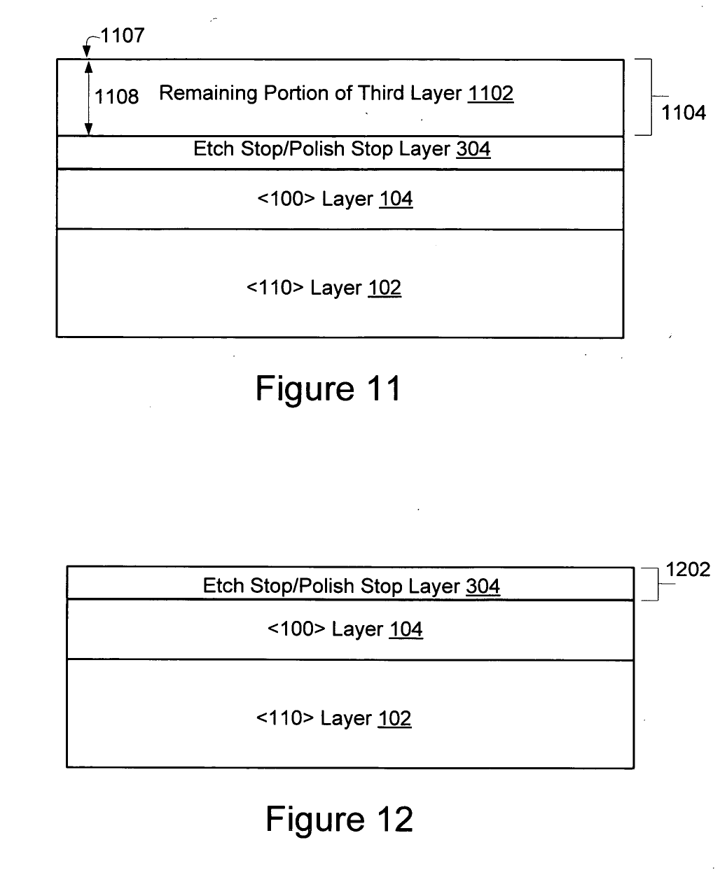

FIG. 11 is a cross sectional side view that illustrates the bonded first and second substrates 300, 900 after a portion of the third layer 302 has been removed 206, leaving behind a remaining portion of the third layer 1102. In an embodiment, the portion of the third layer 302 may be removed by grinding, although other methods may be used. After a portion of the third layer 302 has been removed 206, the remaining portion of the third layer 1102 may have a thickness 1104. In an embodiment, this thickness 1104 may be between about 15 and 25 microns. In another embodiment, the thickness 1104 may be about 20 microns, although it may be different in other embodiments. Having a thickness as great as 15 microns, 20 microns or more after grinding may allow avoidance of a high dislocation density within the second layer 104. If the third layer 1102 were ground thinner, the mechanical stresses generated in the grinding process could cause a higher dislocation density within the second layer 104 in some embodiments. In an embodiment, the dislocation density within the second layer 104 may be about 100/cm² or less. In another embodiment, the second layer 104 may have a dislocation density of about 10/cm² or less. The second layer 104 in the completed substrate 100 may have substantially the same dislocation density.

The thickness 1104 may be an average thickness that varies at different point across the surface. Grinding may result in large variations in thickness in some embodiments. In some embodiments, the thickness 1108 at one point 1107 may be greater or less than the average thickness 1104 by as much as 5 microns. In some embodiments, there may be a maximum difference between the average thickness 1104 and a thickness at another point of greater than five microns. Thus, the thickness of the remaining portion of the third layer 1102 may be uneven and significantly vary from the average thickness 1104.

FIG. 12 is a cross sectional side view that illustrates the bonded first and second substrates 300, 900 after substantially all of the remaining portion of the third layer 1102 has been removed 208. In an embodiment, the remaining portion of the third layer 1102 may be removed by etching. In such an embodiment, the materials of the third layer 302 and the etch stop/polish stop layer 304 may be chosen so a selected etchant is highly selective to the material of the third layer 302. In various embodiments, the selectivity of the etchant may be at least about 10:1, at least about 100:1, at least about 1000:1, or a different selectivity. In an embodiment, the remaining portion of the third layer 1102 may be removed by a polishing process. In such an embodiment, the materials of the third layer 302 and the etch stop/polish stop layer 304 may be chosen so a selected polishing process is highly selective to the material of the third layer 302. In various embodiments, the selectivity of the polishing process may be at least about 10:1, at least about 100:1, at least about 1000:1, or a different selectivity.

The selectivity of the etchant or polishing method may allow removal 208 of substantially all of the remaining portion of the third layer 1102 without transferring the unevenness of the thickness 1104 of the remaining portion of the third layer 1102 to the etch stop/polish stop layer 304. After removing 208 substantially all of the remaining portion of the third layer 1102, the etch stop/polish stop layer 304 may have a highly uniform thickness, where the thicknesses at substantially every point of the layer 304 may be within about five angstroms or less of an average thickness 1202, in one embodiment. In another embodiment, the thickness of substantially every point of the etch stop/polish stop layer 304 may be within about one angstrom to about five angstroms of the average thickness 1202. In another embodiment, the thickness of substantially every point of the etch stop/polish stop layer 304 may be within about two angstroms or less of the average thickness 1202.

The etch stop/polish stop layer 304 may then be removed 210. FIG. 1, described above, is a cross sectional side view that illustrates the composite substrate 100 after the etch stop/polish stop layer 304 has been removed 210. The materials of the etch stop/polish stop layer 304 and the second layer 104 may be chosen so an etchant or polishing method used to remove the etch stop/polish stop layer 304 may be highly selective to the etch stop/polish stop layer 304. In various embodiments, the selectivity of the etchant or polishing process may be at least about 10:1, at least about 100:1, at least about 1000:1, or a different selectivity. Such selectivity may allow the thickness of the second layer 104 to be extremely uniform, where the thicknesses of the layer 104 at substantially every point of the layer 104 may be within about five angstroms or less of an average thickness 106, in one embodiment. In another embodiment, the thickness of each part of the second layer 104 may be within about one angstrom to about five angstroms of the average thickness 106. In another embodiment, the thickness of the layer 104 at substantially every point of the layer 104 may be within about two angstroms or less of an average thickness 106.

Thus, a composite substrate 100 may be formed. The composite substrate 100 may have two semiconductor layers 102, 104, each with a different crystal orientation. The thickness of the second layer 104 may be uniform, with every point being close to an average thickness 106.

IV. Example Use of Substrate 100

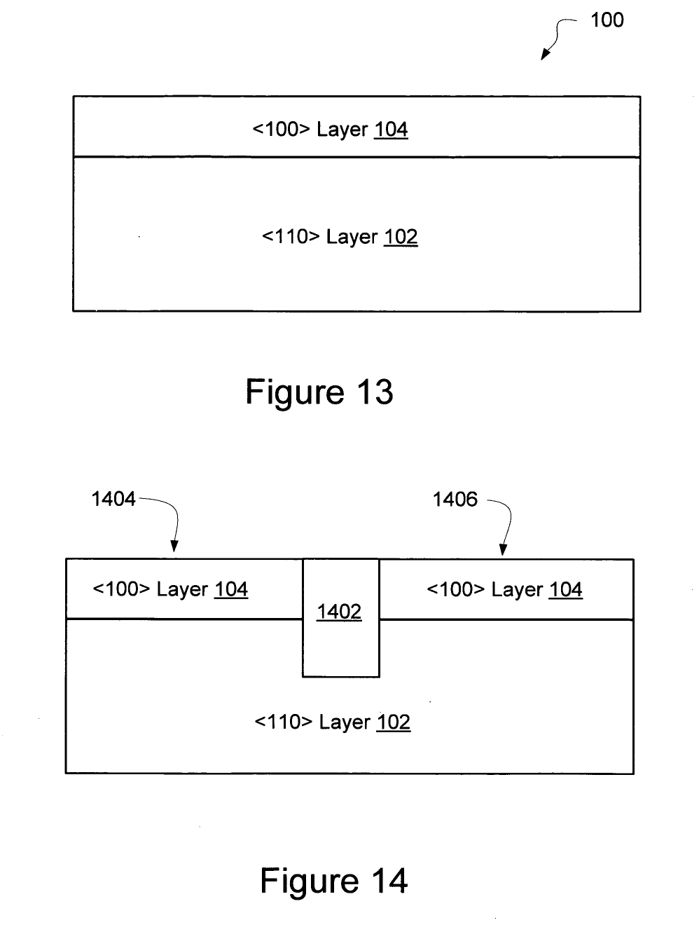

FIGS. 13 through 18 are cross sectional side views that illustrate one use to which the substrate 100 may be put. In other embodiments, the substrate 100 may be used differently. In the described embodiment, the first layer 102 comprises single crystal silicon with a <110> crystal orientation and the second layer 104 comprises single crystal silicon with a <100> crystal orientation. In other embodiments the first and second layers 102, 104 may comprise other materials and/or have other crystal orientations.

FIG. 13 is a cross sectional side view that illustrates the composite substrate 100 of FIG. 1. This substrate 100 may be modified to form <110> and <100> crystal orientation regions at its surface, on which p- and n-type devices may be formed.

FIG. 14 is a cross sectional side view that illustrates the composite substrate 100 after formation of a trench isolation structure 1402, according to one embodiment of the present invention. Any suitable method may be used to form the trench isolation structure 1402, and it may comprise any suitable material. The trench isolation structure 1402 may divide the second layer 104 into a first region 1404 isolated from a second region 1406.

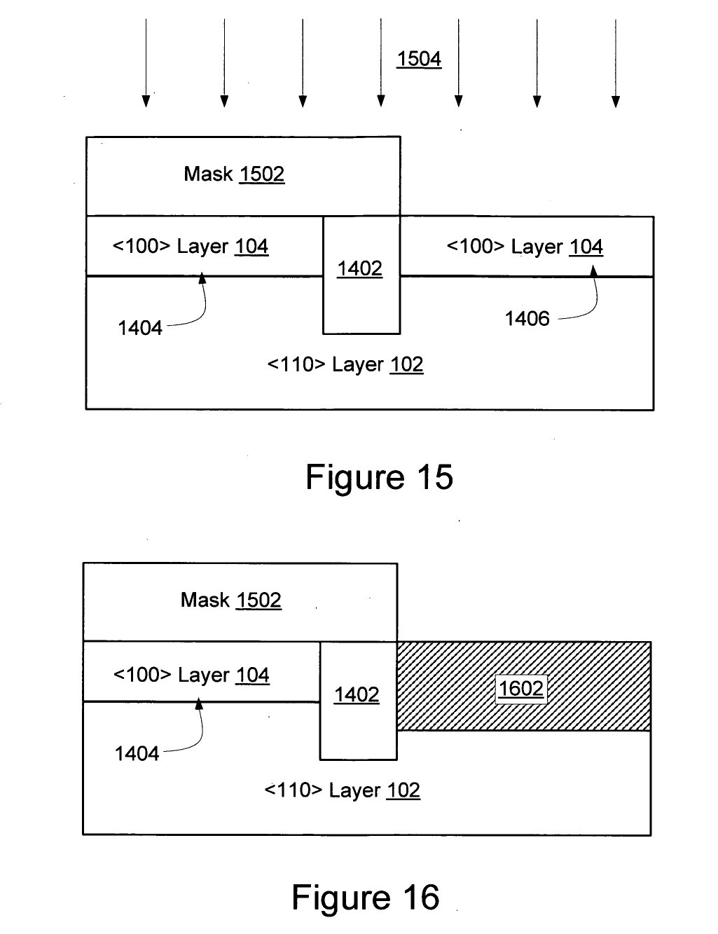

FIG. 15 is a cross sectional side view that illustrates the composite substrate 100 after formation of a mask 1502 over the first region 1404 of the second layer 104, according to one embodiment of the present invention. Any suitable method may be used to form the mask 1502. The mask 1502 may be, for example, a patterned layer of photoresist material. The mask 1502 may protect the first region 1404 of the second layer 104 from an amorphizing implant 1504, while leaving the second region 1406 of the second layer 104 exposed to the amorphizing implant 1504.

In an embodiment, the amorphizing implant 1504 may comprise ions that dope the substrate 100. In an embodiment with a silicon substrate 100, arsenic, germanium, or silicon ions 1504 may be implanted into the second region 1406 of the second layer 104 to amorphize that region 1406, although other ions may be implanted. In some embodiments, the amorphizing implant 1504 may comprise dopants that may be about the same size or a little bit larger than the atoms that make up the second layer 104. The dopants may be neutral, or may n- or p-type dopants. If such dopants are used, doping later used to make transistors on the substrate 100 may compensate for the dopants already present. For example, if an n-type dopant is used and a p-type transistor is formed on that portion of the substrate, extra p-type dopants may be used when making the transistor than would be used absent the doping. In other embodiments, the dopants may be chosen to correctly dope the substrate for one or more of the later-formed devices.

In an embodiment, the amorphizing implant 1504 may be done with silicon ions having an energy in the range of 6-8 keV and a dose of 1×10¹⁴ to 1×10¹⁵ atoms/cm², and in another embodiment the doping may be done at about 7 keV and a dose of about 5×10¹⁴ atoms/cm². Other ions and other process conditions may be used in other embodiments.

FIG. 16 is a cross sectional side view that illustrates the composite substrate 100 after the amorphizing implant 1504, according to one embodiment. The amorphizing implant 1504 has amorphized the formerly crystalline structure of the second region 1406 of the second layer 104, resulting in an amorphous region 1602. In an embodiment, some of the first layer 102 has been amorphized by the amorphizing implant as well, and become part of the amorphous region 1602.

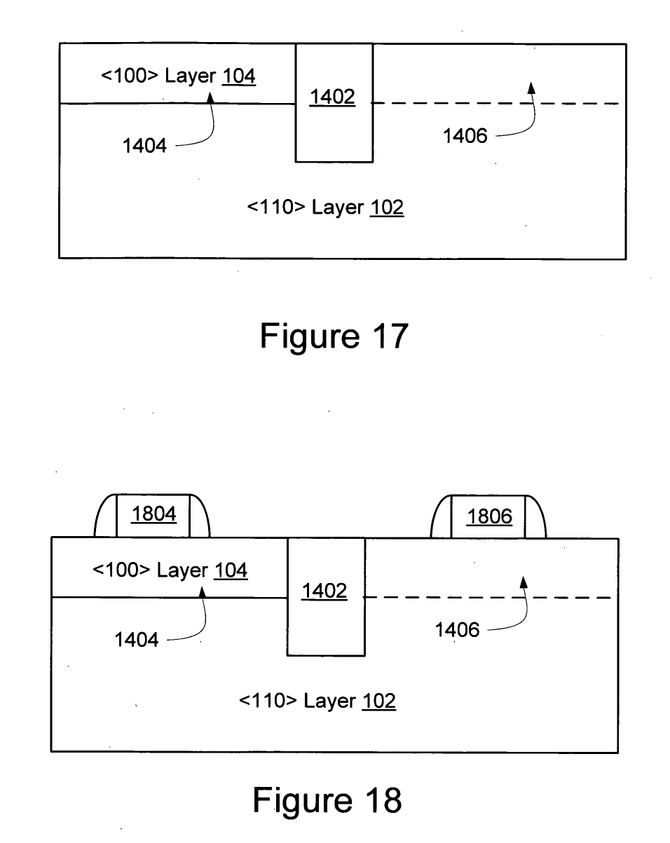

FIG. 17 is a cross sectional side view that shows the substrate 100 after the amorphized region 1602 has recrystallized, according to one embodiment, resulting in a top layer having a first region 1404 with a first crystal orientation (<100> in this embodiment) and a second region 1406 with a second crystal orientation (<110> in this embodiment). In an embodiment, the amorphized region 1602 may be recrystallized by annealing the substrate 100. The amorphized region 1602 may recrystallize with the atoms of that region 1602 having the same crystal orientation as the orientation of the non-amorphized portion to which the formerly amorphous region 1602 is adjacent. For example, the amorphized region 1602 as shown in FIG. 16 is adjacent to first layer 102 with a <110> crystal orientation. Thus, the amorphized region 1602 may have a <110> crystal orientation after recrystallization. The second region 1406 of the second layer 104, which formerly had a <100> crystal orientation, has a <110> crystal orientation at this point. In other embodiments, one or both of the regions 1404, 1406 may have a different crystal orientation than that shown in FIG. 17.

In an embodiment, the substrate 100 may be annealed at a temperature between about 600-900 degrees Celsius. In some embodiments, if the substrate 100 is annealed at higher temperatures it may be annealed for a duration of several minutes, and if the substrate 100 is annealed at lower temperatures it may be annealed for a duration of several hours. In an embodiment, the substrate may be annealed at about 800 degrees Celsius for around 10 minutes. In other embodiments, different anneals may be performed.

FIG. 18 is a cross sectional side view that illustrates devices, such as transistors, formed on the substrate 100, according to another embodiment of the present invention. A p-type planar transistor, including a gate electrode 1806, spacers, gate dielectric, and other structures is on the region 1406 with <110> crystal orientation. An n-type planar transistor, including a gate electrode 1804, spacers, gate dielectric, and other regions is on the region 1404 with <100> crystal orientation. The isolation structure 1402 isolates the two transistors from each other. Thus, the composite substrate 100 of FIG. 1 may be used to allow devices with each n- or p-type device being on a region of the substrate 100 with the appropriate crystal orientation.

While FIGS. 13 through 18 illustrate one use to which the composite substrate 100 may be put, in other embodiments, the composite substrate 100 may be used in different ways.

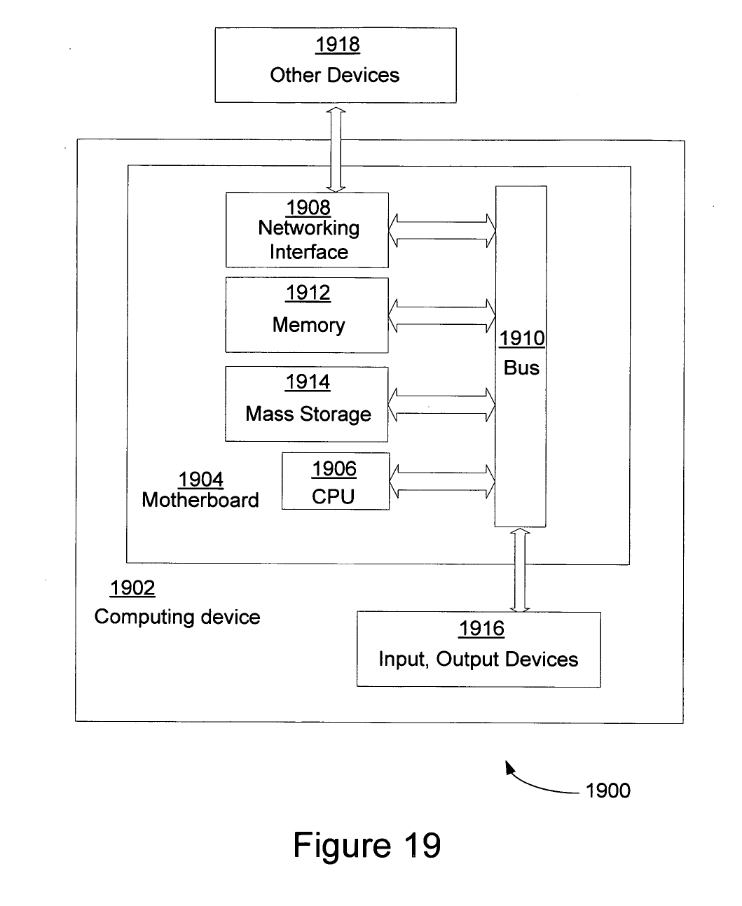

FIG. 19 illustrates a system 1900 in accordance with one embodiment of the present invention. One or more devices formed on a substrate 100 having regions 1404, 1406 with different crystal orientations as described above may be included in the system 1900 of FIG. 19. As illustrated, for the embodiment, system 1900 includes a computing device 1902 for processing data. Computing device 1902 may include a motherboard 1904. Coupled to or part of the motherboard 1904 may be in particular a processor 1906, and a networking interface 1908 coupled to a bus 1910. A chipset may form part or all of the bus 1910.

Depending on the applications, system 1900 may include other components, including but are not limited to volatile and non-volatile memory 1912, a graphics processor (integrated with the motherboard 1904 or connected to the motherboard as a separate removable component such as an AGP or PCI-E graphics processor), a digital signal processor, a crypto processor, mass storage 1914 (such as hard disk, compact disk (CD), digital versatile disk (DVD) and so forth), input and/or output devices 1916, and so forth.

In various embodiments, system 1900 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

I claim:

1. A method for making a semiconductor device, comprising:
bonding a first substrate, the first substrate including a first layer comprising a first material, a second layer on the first layer, the second layer comprising a second material different than the first material, and a third layer comprising a semiconductor material with a first crystal orientation, the semiconductor material being different than the second material, to a second substrate to form a composite substrate, the second substrate comprising the semiconductor material with a second crystal orientation different than the first crystal orientation;
removing substantially all of the first layer from the bonded first and second substrates; and
removing the second layer.

2. The method of claim 1, wherein substantially all of the second layer is exposed after removing substantially all of the first layer, wherein substantially all points of the exposed second layer are within about five angstroms or less of an average thickness of the second layer, and wherein the average thickness of the second layer is about one micron or less.

3. The method of claim 1, wherein bonding the first substrate to the second substrate comprises bonding the third layer of the first substrate directly to the semiconductor material of the second substrate.

4. The method of claim 1, wherein removing the first layer comprises:
grinding away a portion of the first layer; and
etching away substantially all of the rest of the first layer that remains after grinding with an etchant, wherein the etchant etches the first material of the first layer at a rate of at least one hundred times as great as it etches the second material of the second layer.

5. The method of claim 1, wherein removing the first layer comprises:
grinding away a portion of the first layer; and
polishing away substantially all of the rest of the first layer that remains after grinding using a polishing method, wherein the polishing method removes the first material of the first layer at a rate of at least one hundred times as great as it removes the second material of the second layer.

6. The method of claim 1, wherein:
the semiconductor material of the third layer of the first substrate and the second substrate is single-crystal silicon; and
each of the first crystal orientation and the second crystal orientation is mutually-exclusively selected from the group consisting of (100) and (110).

7. The method of claim 1, wherein:
the first substrate is a silicon-on-insulator wafer;
the first material of the first layer is substantially the same as the semiconductor material of the third layer; and
the second layer is a buried oxide layer.

8. The method of claim 1, wherein:
the first material of the first layer of the first substrate comprises silicon;
the second material of the second layer of the first substrate comprises silicon germanium with at least about 20% germanium; and
the semiconductor material of the third layer of the first substrate comprises silicon.

9. The method of claim 1, wherein:
the first material of the first layer of the first substrate comprises the semiconductor material of the third layer of the first substrate;
the semiconductor material of the first and third layers has a crystal structure; and
the second material of the second layer of the first substrate comprises the semiconductor material, with an at least partially amorphous structure.

10. The method of claim 1, wherein:
the first material of the first layer of the first substrate comprises the semiconductor material of the third layer of the first substrate; and
the second material of the second layer of the first substrate comprises the semiconductor material doped with another element.

11. A semiconductor device, comprising:
a semiconductor substrate with a first layer and a second layer on the first layer, the first layer comprising a semiconductor material with a first crystal orientation, and the second layer comprising the semiconductor material with a second crystal orientation different than the first crystal orientation; and
wherein the second layer has a thickness less than about one micron, and the thickness varies less than about 5 angstroms.

12. The device of claim 11, wherein the substrate is part of a wafer having a top surface with a substantially circular shape and a diameter greater than about 200 millimeters.

13. The device of claim 12, wherein the second layer is substantially free of pits.

14. The device of claim 11, wherein the substrate has a dislocation density less than about 10/cm².

15. A method for making a semiconductor device, comprising:
bonding a first substrate, the first substrate including an first layer, a second layer, and a third layer, the second layer being selected from the group consisting of an etch stop layer and a polish stop layer, the first layer comprising a semiconductor material with a first crystal orientation, to a second substrate comprising the semiconductor material with a second crystal orientation different than the first crystal orientation, wherein the first layer is directly bonded to the second substrate;
removing some of the third layer after the first substrate has been bonded to the second substrate, leaving behind a remaining portion of the third layer, the remaining portion having an average thickness, wherein a first point of the remaining portion has a first thickness greater than the average thickness and a second point of the remaining portion has a second thickness less than the average thickness, the difference between the first thickness and second thickness being greater than a micron;
performing a process selected from the group consisting of an etching process and a polishing process, wherein an etching process is performed if the second layer is an etch stop layer and a polishing process is performed if the second layer is a polish stop layer, to remove substantially all of the remaining thickness of the third layer and expose the second layer, substantially all points of the exposed second layer being within about five angstroms or less of an average thickness of the exposed second layer; and
removing substantially all of the second layer to leave behind the first layer of the semiconductor material with the first crystal orientation bonded to the second substrate of the semiconductor material with the second crystal orientation different than the first crystal orientation, substantially all points of the first layer being within about five angstroms or less of an average thickness of the second layer after removal of the second layer.

16. The method of claim 15, further comprising forming the first substrate.

17. The method of claim 16, wherein forming the first substrate comprises:
growing the second layer comprising silicon-germanium middle layer on the third layer comprising silicon; and
growing the third layer comprising silicon on the second layer.

18. The method of claim 16, wherein forming the first substrate comprises implanting ions into a layer of the semiconducting material to form an implanted layer at a depth in the layer of semiconducting material, the portion of the layer of semiconducting material above the implanted layer being at least part of the first layer, the implanted layer being the second layer, and the portion of the layer of semiconducting material below the implanted layer being the third layer.

19. The method of claim 18, wherein the implanted layer comprises a layer of amorphized semiconducting material.

20. The method of claim 18, wherein the implanted layer comprises a layer of doped semiconducting material.

21. The method of claim 18, further comprising growing additional semiconducting material on the portion of the layer of semiconducting material above the implanted layer after implanting ions, the additional semiconducting material being part of the first layer.
